(19) United States
(12) Patent Application Publication
(10) Pub. No.: US 2024/0396282 A1
(43) Pub. Date: Nov. 28, 2024

(54) DISCHARGE ELECTRODE, METHOD OF MANUFACTURING DISCHARGE ELECTRODE, AND ELECTRONIC DEVICE MANUFACTURING METHOD

(71) Applicant: Gigaphoton Inc., Tochigi (JP)

(72) Inventors: Yoichi SASAKI, Oyama-shi (JP); Junichi FUJIMOTO, Oyama-shi (JP)

(73) Assignee: Gigaphoton Inc., Tochigi (JP)

(21) Appl. No.: 18/796,337

(22) Filed: Aug. 7, 2024

Related U.S. Application Data
(63) Continuation of application No. PCT/JP2022/014691, filed on Mar. 25, 2022.

(51) Int. Cl. H01S 3/038; G03F 7/20

(52) U.S. Cl. CPC H01S 3/0388; H01S 3/0381; H01S 3/0382; G03F 7/2006

(57) ABSTRACT

A discharge electrode according to an aspect of the present disclosure is for use in a gas laser apparatus that excites a laser gas containing fluorine by discharge, and includes a cathode electrode that extends in one direction, and an anode electrode that extends in the one direction and that is disposed facing the cathode electrode in a discharge direction orthogonal to the one direction. At least one of the cathode electrode and the anode electrode includes an electrode substrate containing a metal, and a dielectric including a first layer having voids provided on a pair of side faces of the electrode substrate. A porosity of the first layer is in a range of 0.5% to 25%.

### CROSS-REFERENCE TO RELATED APPLICATIONS

The present application is a continuation application of International Application No. PCT/JP2022/014691, filed on Mar. 25, 2022, the entire contents of which are hereby incorporated by reference.

### BACKGROUND

### 1. Technical Field

The present disclosure relates to a discharge electrode, a method of manufacturing a discharge electrode, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as a KrF laser beam and an ArF laser beam, chromatic aberration may occur. As a result, the resolution may decrease. Given this, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (etalon or grating, etc.) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: Japanese Unexamined Patent Application Publication No. 2004-179599

### SUMMARY

A discharge electrode according to an aspect of the present disclosure is for use in a gas laser apparatus that excites a laser gas containing fluorine by discharge, and includes a cathode electrode and an anode electrode. The cathode electrode extends in one direction. The anode electrode extends in the one direction and is disposed facing the cathode electrode in a discharge direction orthogonal to the one direction. At least one of the cathode electrode and the anode electrode includes an electrode substrate containing a metal, and a dielectric including a first layer having voids provided on a pair of side faces of the electrode substrate. A porosity of the first layer is in a range of 0.5% to 25%.

A method of manufacturing a discharge electrode according to one aspect of the present disclosure is a method of manufacturing a discharge electrode for use in a gas laser apparatus, and the method includes a formation process of a dielectric on a side face of an electrode substrate containing a metal. The formation process of the dielectric includes a first step of forming a first layer having voids by thermally spraying a dielectric material on the side face of the electrode substrate, and a second step of forming a second layer having a porosity different from a porosity of the first layer by thermally spraying the dielectric material on a surface of the first layer formed on the side face of the electrode substrate.

An electronic device manufacturing method according to an aspect of the present disclosure includes generating a laser beam with a gas laser apparatus, outputting the laser beam to an exposure apparatus, and exposing a photosensitive substrate to the laser beam in the exposure apparatus. The gas laser apparatus excites a laser gas containing fluorine by discharge using a discharge electrode. The discharge electrode includes a cathode electrode that extends in one direction, and an anode electrode that extends in the one direction and that is disposed facing the cathode electrode in a discharge direction orthogonal to the one direction. At least one of the cathode electrode and the anode electrode includes an electrode substrate containing a metal and a dielectric including a first layer having voids provided on a pair of side faces of the electrode substrate, and a porosity of the first layer is in a range of 0.5% to 25%.

### BRIEF DESCRIPTION OF THE DRAWINGS

Some embodiments of the present disclosure will be described below, by way of example only, with reference to the accompanying drawings.

FIG. 1 is a side view schematically illustrating a configuration of a gas laser apparatus according to a comparative example.

FIG. 2 is a sectional view schematically illustrating a configuration of a gas laser apparatus according to a comparative example.

FIG. 3 is a sectional view illustrating a configuration near a discharge electrode in detail.

FIG. 4 is a contour diagram illustrating a simulation result of electric field strength.

FIG. 5 is a graph illustrating electric field strength at each position in an X direction.

FIG. 6 is a sectional view schematically illustrating a configuration of a discharge electrode according to a first embodiment.

FIG. 7 is a diagram schematically illustrating a principle of thermal spraying of a dielectric material.

FIG. 8 is a graph schematically illustrating relationship between a porosity and a wear rate of a low-density ceramic.

FIG. 9 is a diagram illustrating a process in which a discharge surface and a dielectric are worn.

FIG. 10 is a diagram illustrating a process in which a discharge surface and a dielectric are worn.

FIG. 11 is a graph illustrating relationship between a porosity and a wear rate.

FIG. 12 is a graph illustrating relationship between a shot count and a wear amount.

FIG. 13 is a sectional view schematically illustrating a configuration of a discharge electrode according to a second embodiment.

FIG. 14 is a diagram illustrating processes included in a method of manufacturing a discharge electrode according to the second embodiment.

FIG. 15 is a graph illustrating relationship between a shot count and a wear amount when first layers and second layers are laminated.

FIG. 16 is a diagram schematically illustrating a configuration example of an exposure apparatus.

### DESCRIPTION OF EMBODIMENTS

### Contents

1. Comparative Example
   1.1 Configuration
   1.2 Operation
   1.3 Problem
2. First Embodiment
   2.1 Configuration and Operation
   2.2 Method of Manufacturing Discharge Electrode
   2.3 Effect
      2.3.1 Cause of wear
      2.3.2 Relationship between Porosity and Wear Rate
      2.3.3 Process in which Discharge Surface and Dielectric are Worn
   2.4 Problem of First Embodiment
3. Second Embodiment
   3.1 Configuration and Operation
   3.2 Method of Manufacturing Discharge Electrode
   3.3 Effect
4. Modification
5. Electronic Device Manufacturing Method

Hereinafter, embodiments of the present disclosure will be described in detail with reference to the drawings. The embodiments described below illustrate some examples of the present disclosure and do not limit contents of the present disclosure. In addition, all configurations and operations described in the embodiments are not necessarily essential as configurations and operations of the present disclosure. Here, the same components are denoted by the same reference numerals, and any redundant description thereof is omitted.

### 1. COMPARATIVE EXAMPLE

First, a comparative example of the present disclosure will be described. The comparative example of the present disclosure is an example recognized by the applicant as known only by the applicant, and is not a publicly known example admitted by the applicant.

### 1.1 Configuration

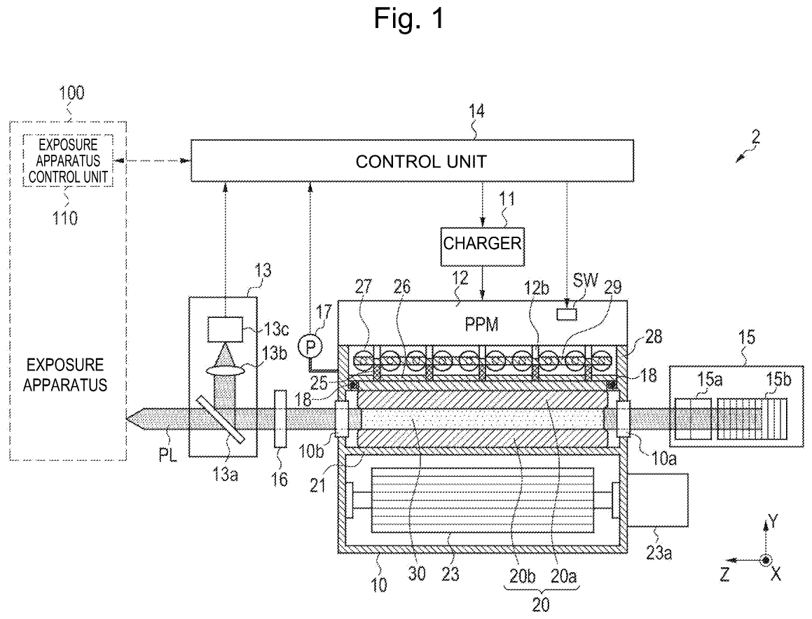

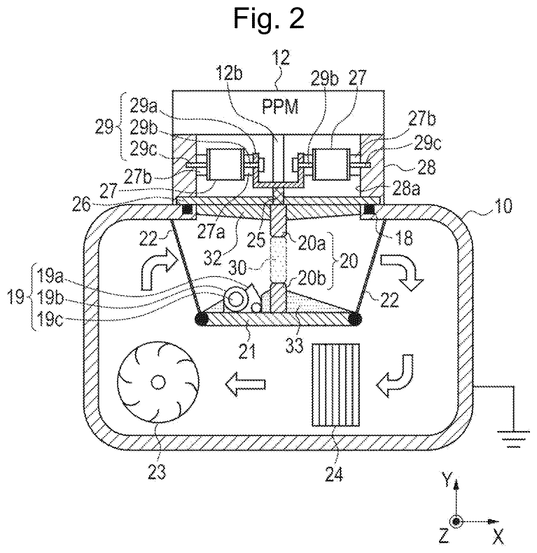

A configuration of a gas laser apparatus 2 according to the comparative example is schematically illustrated in FIG. 1 and FIG. 2. FIG. 1 schematically illustrates the configuration of the gas laser apparatus 2. FIG. 2 is a sectional view of the gas laser apparatus 2 illustrated in FIG. 1, from a Z direction. The gas laser apparatus 2 is a discharge excitation type gas laser apparatus that excites a laser gas by discharge, and is, for example, an excimer laser apparatus.

In FIG. 1, a traveling direction of a pulse laser beam PL output from the gas laser apparatus 2 is defined as the Z direction. A discharge direction to be described later is defined as a Y direction. Further, a direction orthogonal to the Z direction and the Y direction is defined as an X direction. The Z direction corresponds to “one direction” according to technology of the present disclosure.

In FIG. 1, the gas laser apparatus 2 includes a laser chamber 10, a charger 11, and a pulse power module (PPM) 12, a pulse energy measuring unit 13, a control unit 14, a pressure sensor 17, and a laser resonator. The laser resonator is formed of a line narrowing module 15 and an output coupling mirror (Output Coupler: OC) 16.

The laser chamber 10 is, for example, a metal container made of an aluminum metal plated with nickel on a surface. As illustrated in FIG. 1 and FIG. 2, a discharge electrode 20, a ground plate 21, wires 22, a fan 23, a heat exchanger 24, a preionization discharge unit 19, an electrically insulating guide 32, and a metal damper 33 are provided in the laser chamber 10. The preionization discharge unit 19 includes a preionization outer electrode 19a, a dielectric pipe 19b, and a preionization inner electrode 19c.

A laser gas is enclosed in the laser chamber 10 as a laser medium. The laser gas contains, for example, argon, krypton, and xenon or the like as a rare gas, neon and helium or the like as a buffer gas, and fluorine and chlorine or the like as a halogen gas.

Further, an opening is formed in the laser chamber 10. An electrically insulating plate 26 is provided via an O-ring 18 as a sealing member so as to close the opening. A plurality of feedthroughs 25 are embedded in the electrically insulating plate 26. On the electrically insulating plate 26, a plurality of peaking capacitors 27 and a holder 28 for holding them are disposed. The PPM 12 is disposed on the holder 28. The laser chamber 10 and the holder 28 are grounded.

The discharge electrode 20 includes a cathode electrode 20a and an anode electrode 20b. The cathode electrode 20a and the anode electrode 20b are disposed such that their discharge surfaces face each other in the laser chamber 10. A space between the discharge surface of the cathode electrode 20a and the discharge surface of the anode electrode 20b is referred to as a discharge space 30. The cathode electrode 20a is supported by the electrically insulating plate 26 on a surface opposite to the discharge surface. The anode electrode 20b is supported by the ground plate 21 on a surface opposite to the discharge surface.

The feedthroughs 25 are connected to the cathode electrode 20a. Further, as illustrated in FIG. 2, the feedthroughs 25 are connected to the peaking capacitors 27 held by the holder 28 via a connecting portion 29. The connecting portion 29 is a member for connecting the peaking capacitors 27 to other components.

A wall 28a defining an internal space of the holder 28 is formed of a metal material such as an aluminum metal. Inside the holder 28, the peaking capacitors 27, the connecting portion 29, and a high voltage terminal 12b of the PPM 12 are disposed. The peaking capacitors 27 are capacitors that supply, to the discharge electrode 20, electric energy received from PPM 12 and stored therein. The peaking capacitors 27 are, for example, ceramic capacitors in which a dielectric material is made of strontium titanate.

The peaking capacitors 27 are disposed in a matrix manner with two peaking capacitors 27 in the X direction and the plurality of peaking capacitors the Z direction. The peaking capacitors 27 are connected in parallel via the connecting portion 29. In each of the peaking capacitors 27, one electrode 27a is connected to the high voltage terminal 12b and the feedthrough 25 via the connecting portion 29, and the other electrode 27b is connected to the wall 28a of the holder 28 via the connecting portion 29.

The connecting portion 29 includes a connecting plate 29a and connecting terminals 29b and 29c. The connecting plate 29a is formed of a conductive plate having a U-shaped cross section, and is connected to the high voltage terminal 12b and the feedthroughs 25.

The ground plate 21 is connected to the laser chamber 10 via the wires 22. The laser chamber 10 is grounded. The ground plate 21 is grounded via the wires 22. An end of the ground plate 21 in the Z direction is fixed to the laser chamber 10.

The fan 23 is a cross-flow fan for circulating the laser gas in the laser chamber 10, and is disposed on an opposite side of the discharge space 30 with respect to the ground plate 21. A motor 23a for rotationally driving the fan 23 is connected to the laser chamber 10.

The laser gas blown out from the fan 23 flows into the discharge space 30. A flow direction of the laser gas flowing into the discharge space 30 is substantially parallel to the X direction. The laser gas flowing out of the discharge space 30 can be sucked into the fan 23 via the heat exchanger 24. The heat exchanger 24 exchanges heat between a refrigerant supplied to an inside of the heat exchanger 24 and the laser gas.

The electrically insulating guide 32 is disposed on a surface of the electrically insulating plate 26 on the side of the discharge space 30 so as to sandwich the cathode electrode 20a. The electrically insulating guide 32 is formed in a shape to guide a flow of the laser gas such that the laser gas from the fan 23 efficiently flows between the cathode electrode 20a and the anode electrode 20b. The electrically insulating guide 32 and the electrically insulating plate 26 are made of, for example, a ceramic such as alumina (Al₂O₃) which is less reactive with a fluorine gas.

The metal damper 33 is disposed on a surface of the ground plate 21 on the side of the discharge space 30 so as to sandwich the anode electrode 20b. The metal damper 33 is made of, for example, a porous nickel metal which is less reactive with the fluorine gas.

The laser chamber 10 is provided with a laser gas supply device and a laser gas exhaust device that are not illustrated. The laser gas supply device includes a valve and a flow rate control valve, and is connected to a gas cylinder containing the laser gas. The laser gas exhaust device includes a valve and an exhaust pump.

At an end of the laser chamber 10, windows 10a and 10b for outputting light generated in the laser chamber 10 to an outside are provided. The laser chamber 10 is disposed such that an optical path of the optical resonator passes through the discharge space 30 and the windows 10a and 10b.

The line narrowing module 15 includes a prism 15a and a grating 15b. The prism 15a expands a beam width of the light output from the laser chamber 10 through the window 10a and transmits the light toward the grating 15b.

The grating 15b is disposed in Littrow arrangement in which an incident angle and a diffracting angle are the same angle. The grating 15b is a wavelength selecting element that selectively extracts light in a vicinity of a specific wavelength according to the diffracting angle. A spectral width of the light returning from the grating 15b through the prism 15a to the laser chamber 10 is line-narrowed.

The output coupling mirror 16 transmits a part of the light output from the laser chamber 10 through the window 10b, and reflects the other part back to the laser chamber 10. A surface of the output coupling mirror 16 is coated with a partially reflective film.

The light output from the laser chamber 10 reciprocates between the line narrowing module 15 and the output coupling mirror 16, and is amplified every time the light passes through the discharge space 30. A part of the amplified light is output as the pulse laser beam PL via the output coupling mirror 16. The pulse laser beam PL is an example of “laser beam” according to the technology of the present disclosure.

The pulse energy measuring unit 13 is disposed in an optical path of the pulse laser beam PL output via the output coupling mirror 16. The pulse energy measuring unit 13 includes a beam splitter 13a, a condensing optical system 13b, and a photosensor 13c.

The beam splitter 13a transmits the pulse laser beam PL with a high transmittance and reflects a part of the pulse laser beam PL toward the condensing optical system 13b. The condensing optical system 13b condenses the light reflected by the beam splitter 13a on a light receiving surface of the photosensor 13c. The photosensor 13c measures pulse energy of the light condensed on the light receiving surface, and outputs a measured value to the control unit 14.

The pressure sensor 17 detects a gas pressure in the laser chamber 10, and outputs a detection value to the control unit 14. The control unit 14 determines the gas pressure of the laser gas in the laser chamber 10 based on the detection value of the gas pressure and a charging voltage of the charger 11.

The charger 11 is a high voltage power source that supplies the charging voltage to a charging capacitor included in the PPM 12. The PPM 12 includes a solid-state switch SW controlled by the control unit 14. When the solid-state switch SW is switched from OFF to ON, the PPM 12 generates a high voltage pulse from the electric energy held in the charging capacitor and applies the high voltage pulse to the discharge electrode 20.

The control unit 14 is a processor that transmits and receives various kinds of signals to and from an exposure apparatus control unit 110 provided in an exposure apparatus 100. For example, the exposure apparatus control unit 110 transmits, to the control unit 14, signals regarding target pulse energy and target oscillation timing of the pulse laser beam PL output to the exposure apparatus 100 or the like.

The control unit 14 generally controls operations of components of the gas laser apparatus 2 based on various kinds of signals transmitted from the exposure apparatus control unit 110, the measured value of the pulse energy, and the detection value of the gas pressure, or the like.

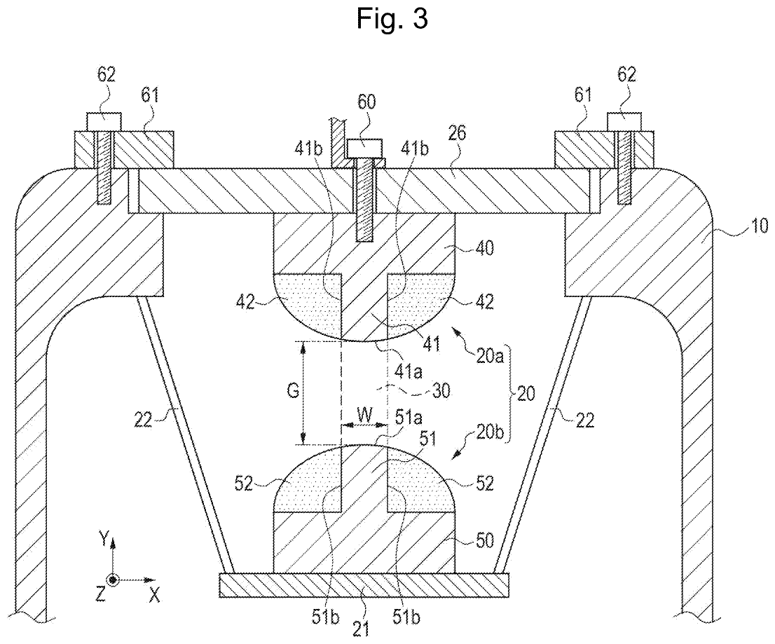

FIG. 3 illustrates a configuration near the discharge electrode 20 in detail. In FIG. 3, the preionization discharge unit 19, the electrically insulating guide 32, the metal damper 33, and the like are not illustrated.

The cathode electrode 20a includes a cathode holder 40, an electrode substrate 41, and dielectrics 42. The cathode holder 40 is made of a metal such as aluminum, and is fixed to the electrically insulating plate 26 by a bolt 60. The cathode holder 40 is connected to the PPM 12 via the bolt 60 outside the laser chamber 10. The electrically insulating plate 26 is fixed to the laser chamber 10 by clamps 61 and bolts 62.

The electrode substrate 41 is made of a metal such as copper or brass, and has a bottom portion embedded in the cathode holder 40. The electrode substrate 41 extends in the Z direction, and has a discharge surface 41a facing the anode electrode 20b in the Y direction and a pair of side faces 41b opposite to each other in the X direction. A cross-sectional shape on an XY plane of the discharge surface 41a is formed of a straight line, a quadratic curve such as an ellipse, or a curve expressed by a special function. The pair of side faces 41b are parallel to each other, and the distance therebetween coincides with a width W of the discharge surface 41a in the X direction. Each of the pair of side faces 41b is parallel to an YZ plane.

The dielectrics 42 are made of a ceramic such as alumina, and are disposed so as to be in close contact with the pair of side faces 41b. One ends of the dielectrics 42 are formed to the vicinity of the discharge surface 41a so as not to cover the discharge surface 41a, and the other ends are in contact with the cathode holder 40.

The anode electrode 20b includes an anode holder 50, an electrode substrate 51, and dielectrics 52. The anode holder 50 is made of a metal such as aluminum, and is held by the ground plate 21.

The electrode substrate 51 is made of a metal such as copper or brass, and has a bottom portion embedded in the anode holder 50. The electrode substrate 51 extends in the Z direction, and has a discharge surface 51a facing the cathode electrode 20a in the Y direction and a pair of side faces 51b opposite to each other in the X direction. A cross-sectional shape on an XY plane of the discharge surface 51a is formed of a straight line, a quadratic curve such as an ellipse, or a curve expressed by a special function. The pair of side faces 51b are parallel to each other, and the distance therebetween coincides with the width W of the discharge surface 51a in the X direction. Each of the pair of side faces 51b is parallel to the YZ plane.

The dielectrics 52 are made of a ceramic such as alumina, and are disposed so as to be in close contact with the pair of side faces 51b. One ends of the dielectrics 52 are formed to the vicinity of the discharge surface 51a so as not to cover the discharge surface 51a, and the other ends are in contact with the anode holder 50.

The discharge surface 41a and the discharge surface 51a face each other and are spaced apart from each other by a gap G in the Y direction so as to form the discharge space 30.

### 1.2 Operation

The control unit 14 controls the laser gas supply device to supply the laser gas into the laser chamber 10, and drives the motor 23a to rotate the fan 23. Accordingly, the laser gas in the laser chamber 10 is circulated.

The control unit 14 receives the signals regarding target pulse energy Et and the target oscillation timing transmitted from the exposure apparatus control unit 110.

The control unit 14 sets a charging voltage Vhv corresponding to the target pulse energy Et in the charger 11. The control unit 14 stores a value of the charging voltage Vhv set in the charger 11. The control unit 14 operates the solid-state switch SW of the PPM 12 in synchronization with the target oscillation timing.

When the solid-state switch SW of the PPM 12 is switched from OFF to ON, a voltage is applied between the preionization inner electrode 19c and the preionization outer electrode 19a of the preionization discharge unit 19 and between the cathode electrode 20a and the anode electrode 20b. As a result, corona discharge occurs in the preionization discharge unit 19, and UV (Ultraviolet) light is generated. When the laser gas in the discharge space 30 is irradiated with the UV light, the laser gas is preionized.

Thereafter, when the voltage between the cathode electrode 20a and the anode electrode 20b reaches a breakdown voltage, main discharge occurs in the discharge space 30. When a discharge direction of the main discharge is a direction in which electrons flow, the discharge direction is a direction from the cathode electrode 20a toward the anode electrode 20b. When the main discharge occurs, the laser gas in the discharge space 30 is excited to output light.

The metal damper 33 suppresses an acoustic wave generated by the main discharge from being reflected back to the discharge space 30 again. Further, as the laser gas is circulated in the laser chamber 10, a discharge product generated in the discharge space 30 moves downstream.

The light output from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser beam PL.

A part of the pulse laser beam PL output from the output coupling mirror 16 enters the pulse energy measuring unit 13. The pulse energy measuring unit 13 measures pulse energy E of the pulse laser beam PL that has entered, and outputs a measured value to the control unit 14.

The control unit 14 stores the measured value of the pulse energy E measured by the pulse energy measuring unit 13. The control unit 14 calculates a difference ΔE between the measured value of the pulse energy E and the target pulse energy Et. Based on the difference ΔE, the control unit 14 feedback-controls the charging voltage Vhv so that the measured value of the pulse energy E becomes the target pulse energy Et.

When the charging voltage Vhv becomes higher than a maximum value in an allowable range, the control unit 14 controls the laser gas supplying device to supply the laser gas into the laser chamber 10 until a predetermined pressure is attained. When the charging voltage Vhv becomes lower than a minimum value in the allowable range, the control unit 14 controls the laser gas exhaust device to exhaust the laser gas from the laser chamber 10 until the predetermined pressure is attained.

### 1.3 Problem

As a shot count increases, the discharge surfaces 41a and 51a of the electrode substrates 41 and 51 are worn, and the gap G between the discharge surfaces 41a and 51a increases. The dielectrics 42 and 52 are provided so as to prevent the width W from spreading as the discharge surfaces 41a and 51a are worn. Here, the shot count is a pulse count of the pulse laser beam PL generated by the main discharge. Hereinafter, the width W of the discharge surfaces 41a and 51a is referred to as a discharge width W. The discharge width W is, for example, about 8 mm.

While the discharge surfaces 41a and 51a are worn as the shot count increases, shapes of the dielectrics 42 and 52 hardly change. More precisely, due to sputtering and etching of the dielectrics 42 and 52 caused by the main discharge, the dielectrics 42 and 52 are degenerated and worn but the amount thereof is small. Since wear rates of the discharge surfaces 41a and 51a and the dielectrics 42 and 52 differ from each other in this way, the discharge surfaces 41a and 51a subside as the shot count increases, and an electric field is concentrated on the ends of the discharge surfaces 41a and 51a.

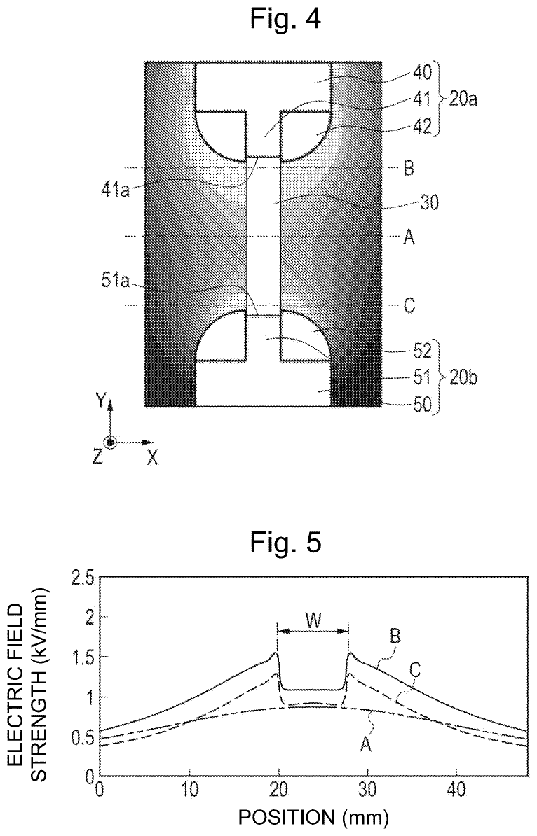

FIG. 4 and FIG. 5 illustrate a simulation result of electric field strength after 30 billion shots from the replacement of the discharge electrode 20. FIG. 4 is a contour diagram of the electric field strength on the XY plane. FIG. 5 is a graph illustrating the electric field intensity at each position in the X direction. In FIG. 5, a dashed line A indicates the electric field strength at a center of the discharge space 30. A solid line B indicates the electric field strength in the vicinity of the discharge surface 41a of the discharge space 30. A broken line C indicates the electric field strength in the vicinity of the discharge surface 51a of the discharge space 30. In the present simulation, a relative dielectric constant of the dielectrics 42 and 52 is set at 10.

According to FIG. 5, even when the shot count increases, the discharge width W hardly changes from the beginning, but it is recognized that the electric field is concentrated at the ends of the discharge surfaces 41a and 51a. As described above, when the electric field is concentrated on the ends of the discharge surfaces 41a and 51a, since the main discharge is divided into two or the like, the pulse laser beam PL becomes unsuitable for exposure or processing because uniformity of a beam profile is impaired. As a result, the discharge electrode 20 is determined to have reached the end of its lifetime, and needs to be replaced.

Therefore, it is required to suppress electric field concentration caused by the increase in the shot count and to extend the life of the discharge electrode 20.

### 2. FIRST EMBODIMENT

### 2.1 Configuration and Operation

The gas laser apparatus 2 according to a first embodiment of the present disclosure has the same configuration as the gas laser apparatus 2 according to the comparative example except that the configuration of the discharge electrode 20 is different. The operation of the gas laser apparatus 2 according to the first embodiment is the same as the operation of the gas laser apparatus 2 according to the comparative example.

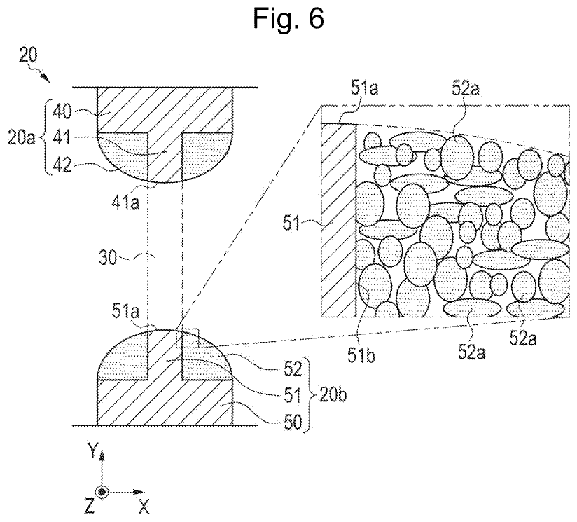

FIG. 6 schematically illustrates a configuration of the discharge electrode 20 according to the first embodiment. The discharge electrode 20 according to the present embodiment differs from the discharge electrode 20 according to the comparative example only in that the dielectrics 42 and 52 are formed of a low-density ceramic.

FIG. 6 illustrates the configuration of the dielectric 52 by a partially enlarged view. In the present embodiment, the dielectric 52 is the low-density ceramic configured as an aggregate of a plurality of ceramic particles 52a, and has voids. The ceramic particles 52a are formed of an oxide such as alumina or yttria (Y₂O₃), or a two-dimensional compound or a three-dimensional compound formed of yttrium (Y), oxygen (O), and fluorine (F) or the like.

A porosity of the dielectric 52 affects the wear rate of the dielectric 52. As will be described in detail later, the wear rate increases as the porosity increases. Therefore, by adjusting the porosity, the wear rate of the dielectric 52 can be brought close to the wear rate of the discharge surface 51a. The porosity is a ratio of volume of the voids to volume of the dielectric 52. In the present disclosure, the porosity refers to a value measured by an underwater gravimetric method.

In order to bring the wear rate of the dielectric 52 close to the wear rate of the discharge surface 51a, the porosity is preferably within a range of 0.5% to 25%, and is more preferably 2% to 15%.

The dielectric 42 has the same configuration as that of the dielectric 52.

### 2.2 Method of Manufacturing Discharge Electrode

The dielectric 42 is formed by thermally spraying a dielectric material onto the side face 41b of the electrode substrate 41 and a surface on the side of the discharge space 30 of the electrode holder 40. Similarly, the dielectric 52 is formed by thermally spraying a dielectric material onto the side face 51b of the electrode substrate 51 and a surface on the side of the discharge space 30 of the electrode holder 50.

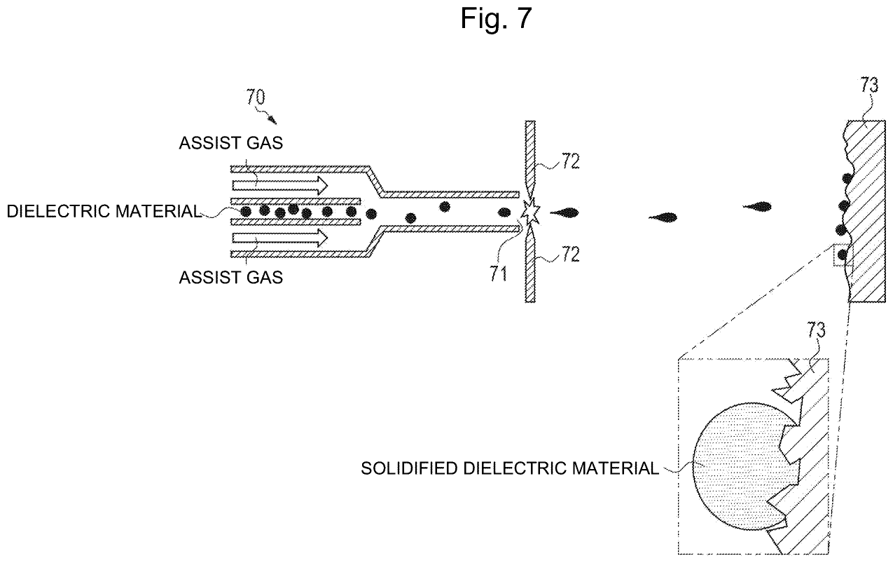

FIG. 7 schematically illustrates a principle of thermal spraying of the dielectric material. The thermal spraying of the dielectric material is carried out using a thermal spraying gun 70. The thermal spraying gun 70 is supplied with a powdery dielectric material such as alumina or yttria and an assist gas which is an inert gas such as nitrogen or argon. The thermal spraying gun 70 carries the dielectric material on the assist gas to a discharge port 71. Electrodes 72 which generate arc discharge are disposed at the discharge port 71. The dielectric material is brought into a molten state by an arc current, and is output from the thermal spraying gun 70 toward a base material 73 that is a target of the thermal spraying. The molten state includes a semi-molten state.

When the dielectric material output from the thermal spraying gun 70 reaches the base material 73, it is stuck to a surface of the base material 73 by an anchor effect. Shots of the dielectric material are applied to the surface of the base material 73, thereby forming a thermal spray coating. In a case where thermal spray coating made of the dielectric material has been already formed on the surface of the base material 73 when the dielectric material output from the thermal spraying gun 70 reaches the base material 73, the dielectric material is bonded to the thermal spray coating by the anchor effect. The anchor effect means that the dielectric material in the molten state enters minute holes or irregularities and is solidified to obtain bonding force.

By having the electrode substrates 41 and 51 and the electrode holders 40 and 50 as the base material 73, thermal spraying of the dielectric material to form a thermal spray coating having a predetermined thickness can lead to formation of the dielectrics 42 and 52 having voids.

The porosity can be adjusted by controlling energy of the dielectric material output from the thermal spraying gun 70. A thermal spray coating having a lower porosity is formed as the energy of the dielectric material increases. Conversely, a thermal spray coating having a higher porosity is formed as the energy of the dielectric material decreases. The energy of the dielectric material can be controlled with a flow rate of the assist gas and the arc current as parameters. The energy of the dielectric material increases as the flow rate of the assist gas or the arc current increases.

### 2.3 Effect

### 2.3.1 Cause of Wear

By making the dielectrics 42 and 52 be the low-density ceramic having voids, the wear rate of the dielectrics 42 and 52 by the main discharge increases. Wear of the dielectrics 42 and 52 results from the sputtering and the etching.

The sputtering is a phenomenon of breaking a bond between the ceramic particles and flicking off the ceramic particles by collision of accelerated charged particles included in discharge plasma generated by the main discharge, and causes physical wear of the dielectrics 42 and 52.

The etching is a phenomenon of causing chemical reaction in the ceramic particles by the discharge plasma of a halogen gas containing fluorine and chlorine or the like, and causes chemical wear of the dielectrics 42 and 52. For example, when plasma containing fluorine acts on alumina, aluminum fluoride (AlF₃) is generated on an alumina surface, the aluminum fluoride volatilizes from the surface, and thus the etching progresses. That is, it is presumed that the chemical reaction represented by the following formula (1) occurs.

Al₂O₃+6F₂→2AlF₃+3F₂O (1)

However, the chemical reaction is not limited thereto, and a case where a fluorine form is a radical or an ion and a case where a product is oxygen fluoride (FO) or the like are also assumed.

### 2.3.2 Relationship between Porosity and Wear Rate

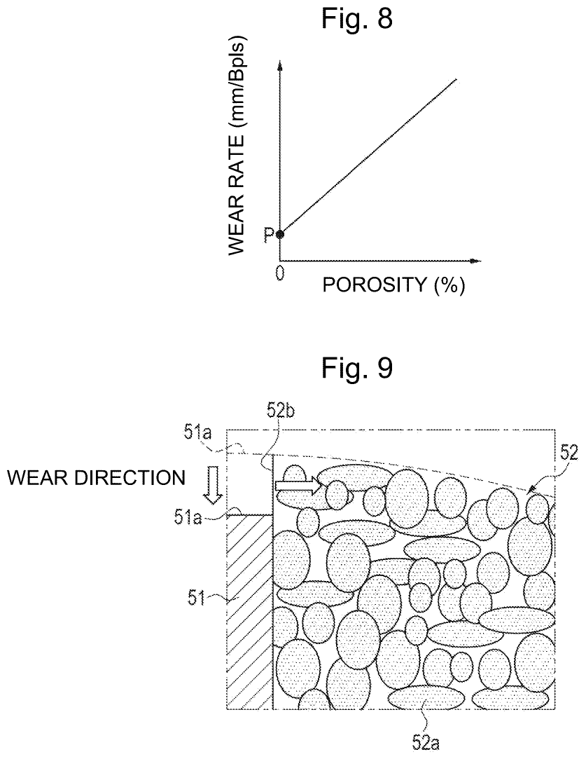

FIG. 8 schematically illustrates relationship between the porosity and the wear rate of the low-density ceramic. The wear rate is defined, for example, as an amount (mm/Bpls) of wear by the sputtering and the etching caused when the low-density ceramic is exposed to the discharge plasma for several billion shots. Bpls stands for “Billion pulses”.

When the porosity is 0% as illustrated by a point P in FIG. 8 which represents a dense ceramic, a wear amount is very small and the wear rate is low. This is because in the dense ceramic, the molecules of the ceramic are bound by intermolecular force that is greater than the energy of the discharge plasma.

On the other hand, when the porosity is higher than 0% which represents a low-density ceramic having voids, the wear rate increases as the porosity increases. This is because the thermally-sprayed ceramic particles 52a are just stuck to the base material 73 by the anchor effect and the energy of the discharge plasma easily causes the sputtering and the etching. Since the same amount of the sputtering and the etching occurs for the discharge plasma having the same energy, the wear rate of the low-density ceramic increases as the porosity increases.

Therefore, the wear rate of the low-density ceramic can be controlled by the porosity. The porosity may be set so as to bring the wear rates of the discharge surfaces 41a and 51a and the dielectrics 42 and 52 close to each other.

### 2.3.3 Process in which Discharge Surface and Dielectric are Worn

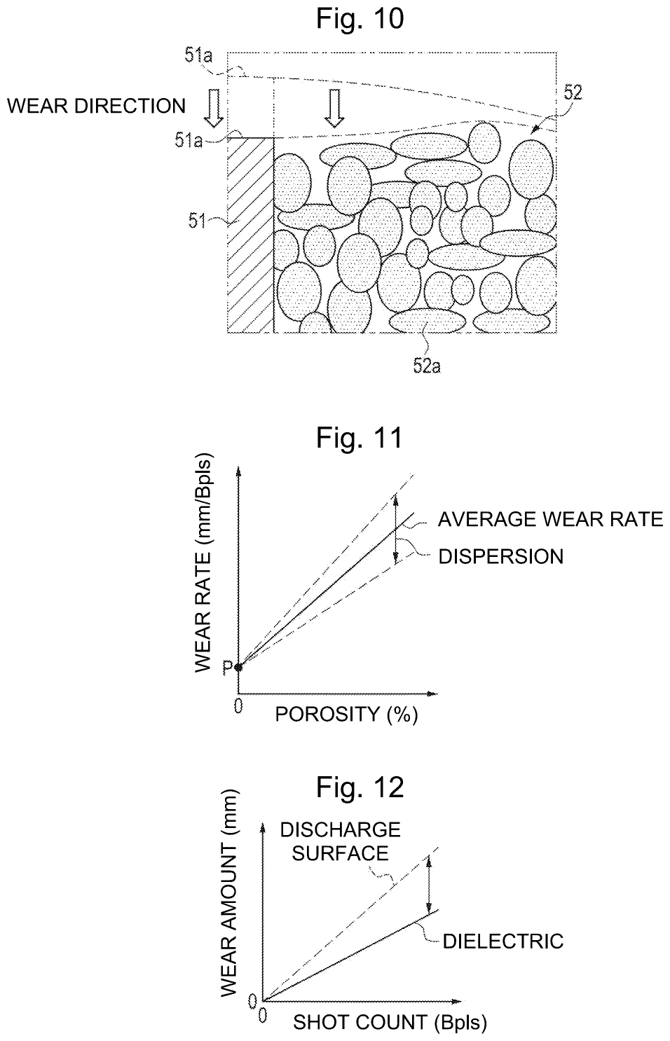

FIG. 9 and FIG. 10 illustrate a process in which the discharge surface 51a and the dielectric 52 are worn in the present embodiment. As illustrated in FIG. 9, as the shot count increases, the discharge surface 51a is worn and subsides as in the comparative example. When the discharge surface 51a subsides, a wall surface 52b of the dielectric 52 is exposed to the discharge plasma. The dielectric 52 undergoes the sputtering and the etching in the vicinity of the wall surface 52b exposed to the discharge plasma, and thus the wear progresses.

As illustrated in FIG. 10, as the wear of the dielectric 52 progresses, the surface of the dielectric 52 lowers. As a result, since the discharge surface 51a and the surface of the dielectric 52 are worn while maintaining initial relationship, a difference in the wear rate between the discharge surface 51a and the dielectric 52 is suppressed. Therefore, subsiding of the discharge surface 51a with respect to the surface of the dielectric 52 is suppressed.

The same applies to a process in which the discharge surface 41a and the dielectric 42 are worn in the present embodiment, and the subsiding of the discharge surface 41a with respect to the surface of the dielectric 42 is suppressed.

In this way, in the present embodiment, since the difference in the wear rate between the discharge surfaces 41a and 51a and the dielectrics 42 and 52 is suppressed, the electric field concentration at the ends of the discharge surfaces 41a and 51a is suppressed. As a result, uniformity of a beam profile is maintained, and the discharge electrode 20 can have a longer life.

### 2.4 Problem of First Embodiment

As described above, for the low-density ceramic, while the wear rate increases as the porosity increases, dispersion of the porosity increases as the porosity increases. Therefore, as illustrated in FIG. 11, as the porosity increases, dispersion of the wear rate with respect to an average wear rate increases. That is, it is easy to control the wear rate when the porosity is low, whereas it is difficult to control the wear rate when the porosity is high.

When the dielectrics 42 and 52 are formed of the low-density ceramic having a single porosity as in the first embodiment, a target wear rate may not be realized depending on the porosity. Therefore, as illustrated in FIG. 12, there may be a large difference with respect to the wear rate of the discharge surfaces 41a and 51a. Since this difference increases as the shot count increases, it may not be possible to sufficiently bring out the effect of using the low-density ceramic depending on the porosity. While FIG. 12 illustrates a case where the wear rate of the dielectrics 42 and 52 is lower than the wear rate of the discharge surfaces 41a and 51a, the result can be the same in a case where the wear rate of the dielectrics 42 and 52 is higher than the wear rate of the discharge surfaces 41a and 51a.

### 3. SECOND EMBODIMENT

### 3.1 Configuration and Operation

Next, the gas laser apparatus 2 according to a second embodiment will be described. The gas laser apparatus 2 according to the second embodiment has the same configuration as the gas laser apparatus 2 according to the first embodiment except that the configuration of the discharge electrode 20 is different. The operation of the gas laser apparatus 2 according to the second embodiment is the same as the operation of the gas laser apparatus 2 according to the comparative example.

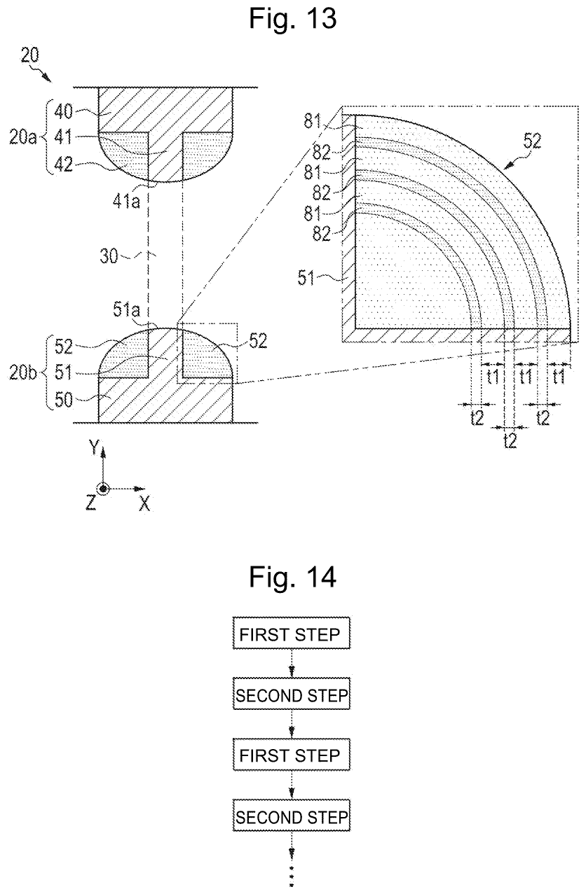

FIG. 13 schematically illustrates the configuration of the discharge electrode 20 according to the second embodiment. The discharge electrode 20 according to the present embodiment is different from the discharge electrode 20 according to the first embodiment in that, even while the dielectrics 42 and 52 are formed of the low-density ceramic, the dielectrics 42 and 52 include a plurality of layers having different porosities.

FIG. 13 illustrates a configuration of the dielectric 52 by a partially enlarged view. In the present embodiment, the dielectric 52 includes a first layer 81 having voids and a second layer 82 having a porosity different from that of the first layer 81. The first layer 81 is formed of the low-density ceramic. The porosity of the first layer 81 is the same as the porosity of the low-density ceramic that makes up the dielectric 52 of the first embodiment, and is preferably in the range of 0.5% to 25%, and more preferably in the range of 2% to 15%. That is, the dielectric 52 of the first embodiment is made up of the same material as the first layer 81.

The second layer 82 has the same configuration as the first layer 81 except for the difference in porosity. The porosity of the second layer 82 is lower than the porosity of the first layer 81. That is, the second layer 82 is formed of a ceramic denser than the first layer 81. The difference in porosity between the first layer 81 and the second layer 82 is preferably 1% or more, and more preferably 3% or more. The porosity of the second layer 82 is, for example, lower than 0.3%.

A plurality of first layers 81 and a plurality of second layers 82 are provided. The first layers 81 and the second layers 82 are alternately laminated. In the present embodiment, a first layer 81 is provided as a top layer of the dielectric 52. The respective first layers 81 have the same porosity. The respective second layers 82 also have the same porosity. The respective first layers 81 have the same thickness. The respective second layers 82 also have the same thickness. In the present disclosure, “same” means that the difference is in the range of ±15%.

In the present embodiment, the thickness of the first layer 81 is larger than the thickness of the second layer 82. In FIG. 13, the thickness of the first layer 81 is t1, and the thickness of the second layer 82 is t2. The thicknesses t1 and t2 are, for example, 0.2 mm or less. The thickness of a bottom layer of the dielectric 52 illustrated in FIG. 13 is larger than the thicknesses of the first layer 81 and the second layer 82.

The dielectric 42 has a configuration similar to that of the dielectric 52, and includes the first layers 81 and the second layers 82 that are alternately laminated. The porosities and the thicknesses or the like of the first layers 81 and the second layers 82 of the dielectric 42 may be the same as those of the first layers 81 and the second layers 82 of the dielectric 52. In addition, the porosities and the thicknesses or the like of the first layers 81 and the second layers 82 of the dielectric 42 may be selected such that the wear rates of the discharge surface 41a of the electrode substrate 41 and the dielectric 42 are equal to each other.

### 3.2 Method of Manufacturing Discharge Electrode

The dielectrics 42 and 52 of the second embodiment can be formed by thermal spraying as in the first embodiment.

FIG. 14 illustrates steps included in the method of manufacturing the discharge electrode 20 according to the second embodiment. The method of manufacturing the discharge electrode 20 includes a formation process of the dielectrics 42 and 52 on the side faces 41b and 51b of the electrode substrates 41 and 51. The formation process of the dielectrics 42 and 52 includes a first step and a second step illustrated in FIG. 14. The first step is a step of forming the first layer 81 by thermally spraying a dielectric material on the side faces 41b and 51b of the electrode substrates 41 and 51. The second step is a step of forming the second layer 82 having the porosity different from that of the first layer 81 by thermally spraying a dielectric material on a surface of the first layer 81 formed on the side faces 41b and 51b of the electrode substrates 41 and 51. The first step and the second step are performed alternately.

The first step and the second step each include a thermal spraying step of applying the arc current to the dielectric material to bring the dielectric material into a molten state, and carrying the dielectric material in the molten state by the assist gas. The porosities of the first layer 81 and the second layer 82 are adjusted by controlling the energy of the dielectric material with use of at least one of the flow rate of the assist gas and the arc current. Therefore, in order to make the porosity of the first layer 81 and the porosity of the second layer 82 different from each other, at least one of the flow rate of the assist gas and the arc current is different between the first step and the second step.

The porosities of the first layer 81 and the second layer 82 are set such that the wear rates of the discharge surfaces 41a and 51a of the electrode substrates 41 and 51 and the dielectrics 42 and 52 are equal to each other when the discharge electrode 20 repeatedly performs the main discharge. The thicknesses of the first layer 81 and the second layer 82 are set such that the wear rates of the discharge surfaces 41a and 51a of the electrode substrates 41 and 51 and the dielectrics 42 and 52 are equal to each other when the discharge electrode 20 repeatedly performs the main discharge.

### 3.3 Effect

For the second layer 82, since the porosity is lower than that of the first layer 81, the wear rate is low, but the dispersion of the wear rate is small. Therefore, by lamination of the first layers 81 and the second layers 82, it is possible to suppress the dispersion of the wear rate as a whole and to approach the target wear rate. That is, by lamination of the first layers 81 and the second layers 82, the wear rate can be made closer to the wear rate of the discharge surfaces 41a and 51a.

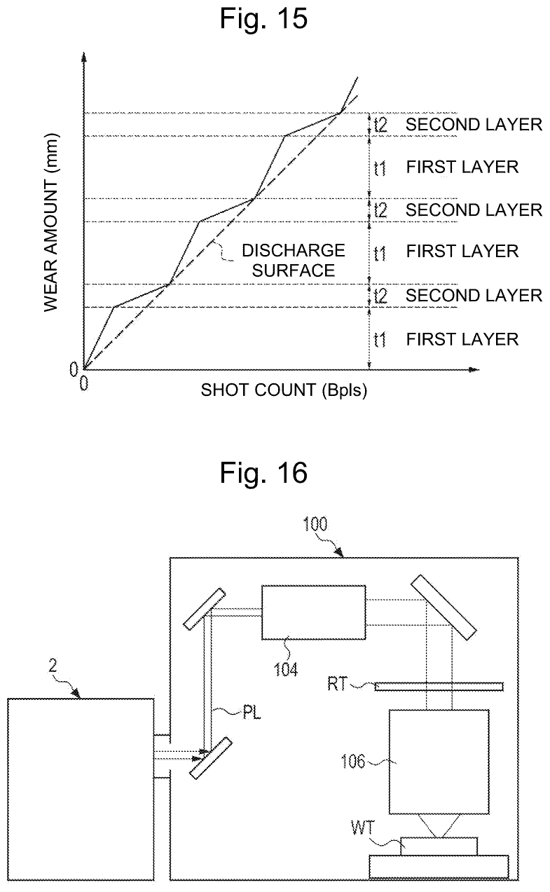

FIG. 15 illustrates relationship between the shot count and the wear amount in a case where the first layers 81 and the second layers 82 are laminated. A solid line indicates the wear amount of the first layers 81 and the second layers 82, and a broken line indicates the wear amount of the discharge surfaces 41a and 51a. As illustrated in FIG. 15, since the wear rates of the first layers 81 and the second layers 82 are different, the wear amount of the dielectrics 42 and 52 does not locally coincide with the wear amount of the discharge surfaces 41a and 51a, but it approaches the wear amount of the discharge surfaces 41a and 51a over a long period of several billion shots.

As described above, according to the second embodiment, the problem of the first embodiment is solved, and the discharge electrode 20 can have a longer life.

### 4. MODIFICATION

Next, various modifications of the first and second embodiments will be described. In the first and second embodiments, both of the dielectrics 42 and 52 are the low-density ceramic, but only one of the dielectrics 42 and 52 may be the low-density ceramic. For example, only the dielectrics 52 of the anode electrode 20b may be the low-density ceramic because the anode electrode 20b is known to be worn faster than the cathode electrode 20a. That is, the dielectrics 42 and/or the dielectrics 52 including voids may be provided on the side faces 41b of the electrode substrate 41 and/or the side faces 51b of the electrode substrate 51 on at least one of the cathode electrode 20a and the anode electrode 20b.

Further, in the first and second embodiments, the gas laser apparatus 2 is a line narrowing laser apparatus, but the gas laser apparatus 2 is limited thereto and it may be a gas laser apparatus which outputs spontaneous oscillation light. For example, instead of the line narrowing module 15, a high reflective mirror may be disposed.

Further, in the first and second embodiments, the gas laser apparatus 2 is an excimer laser apparatus, but it may be an F₂ molecular laser apparatus using a laser gas containing a fluorine gas and a buffer gas, instead. That is, the gas laser apparatus according to the present disclosure may be any gas laser apparatus that excites a laser gas containing fluorine by discharge.

### 5. ELECTRONIC DEVICE MANUFACTURING METHOD

FIG. 16 schematically illustrates a configuration example of the exposure apparatus 100. The exposure apparatus 100 includes an illumination optical system 104 and a projection optical system 106. The illumination optical system 104 illuminates a reticle pattern of an unillustrated reticle disposed on a reticle stage RT with the pulse laser beam PL which has entered from the gas laser apparatus 2, for example. The projection optical system 106 performs reduction projection of the pulse laser beam PL transmitted through the reticle and forms an image on an unillustrated workpiece disposed on a workpiece table WT. The workpiece is a photosensitive substrate such as a semiconductor wafer coated with photoresist.

The exposure apparatus 100 synchronously translates the reticle stage RT and the workpiece table WT to expose the workpiece to the pulse laser beam PL reflecting the reticle pattern. After the reticle pattern is transferred onto the semiconductor wafer by an exposure process described above, a semiconductor device can be manufactured through a plurality of processes. The semiconductor device is an example of “electronic device” in the present disclosure.

Note that the gas laser apparatus 2 can be used not only for manufacturing of an electronic device but also for laser processing such as drilling.

The description above is intended to be illustrative and the present disclosure is not limited thereto. Therefore, it would be obvious to those skilled in the art that various modifications to the individual embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A discharge electrode for use in a gas laser apparatus that excites a laser gas containing fluorine by discharge, the discharge electrode comprising:
a cathode electrode that extends in one direction; and
an anode electrode that extends in the one direction and that is disposed facing the cathode electrode in a discharge direction orthogonal to the one direction,
at least one of the cathode electrode and the anode electrode including
an electrode substrate containing a metal and a dielectric including a first layer having voids provided on a pair of side faces of the electrode substrate, and
a porosity of the first layer is in a range of 0.5% to 25%.

2. The discharge electrode according to claim 1, wherein
both the cathode electrode and the anode electrode include the electrode substrate and the dielectric.

3. The discharge electrode according to claim 1, wherein
the porosity is in a range of 2% to 15%.

4. The discharge electrode according to claim 1, wherein
the porosity is a value measured by an underwater gravimetric method.

5. The discharge electrode according to claim 1, wherein
the dielectric includes a second layer having a porosity different from the porosity of the first layer.

6. The discharge electrode according to claim 5, wherein
the first layer comprises a plurality of first layers and the second layer comprises a plurality of second layers, and
the first layers and the second layers are alternately laminated.

7. The discharge electrode according to claim 6, wherein
the respective first layers have a same porosity, and
the respective second layers have a same porosity.

8. The discharge electrode according to claim 7, wherein
the respective first layers have a same thickness, and
the respective second layers have a same thickness.

9. The discharge electrode according to claim 6, wherein
a top layer of the dielectric is the first layer.

10. The discharge electrode according to claim 6, wherein
a thickness of the first layer is greater than a thickness of the second layer.

11. The discharge electrode according to claim 6, wherein
a porosity of the second layer is smaller than a porosity of the first layer.

12. The discharge electrode according to claim 7, wherein
a difference in porosity between the first layer and the second layer is 1% or more.

13. The discharge electrode according to claim 12, wherein
the difference in porosity between the first layer and the second layer is 3% or more.

14. A method of manufacturing a discharge electrode for use in a gas laser apparatus, the method comprising
a formation process of a dielectric on a side face of an electrode substrate containing a metal,
the formation process of the dielectric including
a first step of forming a first layer having voids by thermally spraying a dielectric material on the side face of the electrode substrate, and
a second step of forming a second layer having a porosity different from a porosity of the first layer by thermally spraying the dielectric material on a surface of the first layer formed on the side face of the electrode substrate.

15. The method of manufacturing a discharge electrode according to claim 14, wherein
the porosities of the first layer and the second layer are set such that wear rates of a discharge surface of the electrode substrate and the dielectric are equal to each other when the discharge electrode repeatedly performs main discharge.

16. The method of manufacturing a discharge electrode according to claim 14, wherein
thicknesses of the first layer and the second layer are set such that wear rates of a discharge surface of the electrode substrate and the dielectric are equal to each other when the discharge electrode repeatedly performs main discharge.

17. The method of manufacturing a discharge electrode according to claim 14, wherein
the first step and the second step each include a thermal spraying step of applying an arc current to the dielectric material to bring the dielectric material into a molten state, and carrying the dielectric material in the molten state by an assist gas.

18. The method of manufacturing a discharge electrode according to claim 17, wherein
at least one of a flow rate of the assist gas and the arc current is different between the first step and the second step.

19. An electronic device manufacturing method comprising:
generating a laser beam with a gas laser apparatus that excites a laser gas containing fluorine by discharge using a discharge electrode, the discharge electrode including
a cathode electrode that extends in one direction and
an anode electrode that extends in the one direction and that is disposed facing the cathode electrode in a discharge direction orthogonal to the one direction,
at least one of the cathode electrode and the anode electrode including
an electrode substrate containing a metal and a dielectric including a first layer having voids provided on a pair of side faces of the electrode substrate, and
a porosity of the first layer is in a range of 0.5% to 25%;
outputting the laser beam to an exposure apparatus; and
exposing a photosensitive substrate to the laser beam in the exposure apparatus.
